(19) United States
(12) Patent Application Publication
(10) Pub. No.: US 2026/0203476 A1
(43) Pub. Date: Jul. 16, 2026

(54) PREDICTION DEVICE, PREDICTION METHOD, AND PREDICTION PROGRAM

(71) Applicant: NTT, Inc., Tokyo (JP)

(72) Inventors: Chao WU, Musashino-shi (JP); Shingo HORIUCHI, Musashino-shi (JP); Nobukazu FUKUDA, Musashino-shi (JP)

(73) Assignee: NTT, Inc., Tokyo (JP)

(21) Appl. No.: 19/131,997

(22) PCT Filed: Dec. 13, 2022
(86) PCT No.: PCT/JP2022/045871

§ 371 Date: May 22, 2025

(51) Int. Cl. G06F 30/27

(52) U.S. Cl. CPC G06F 30/27

(57) ABSTRACT

A prediction device includes a model generation unit, a prediction value error calculation unit, a difference error calculation unit, an update weight learning unit, and a model update unit. The model generation unit generates a base model of a prediction model configured to predict a future value using information on a future event. The prediction value error calculation unit acquires a real-time observation value, and calculates a prediction error between the real-time observation value and a prediction value by a prediction model. The difference error calculation unit acquires a real-time observation value and calculates a difference error between the real-time observation value and a prediction value by the prediction model. The update weight learning unit acquires a prediction error and a difference error, and updates the update weight to minimize a total error between the prediction value and the real-time observation value at a plurality of past times.

### TECHNICAL FIELD

The present invention relates to a prediction device, a prediction method, and a prediction program.

### BACKGROUND ART

Techniques for predicting future values of objects from past values of prediction objects or related objects using a time-series prediction model are known. A vector auto regressive (VAR) model and an autoregressive moving average (ARMA) model are known as time-series prediction models. Examples of VAR models are disclosed in NPL 1. Examples of ARMA models are disclosed in NPL 2.

### CITATION LIST

### Non Patent Literature

[NPL 1] Jethro Dowell, Student Member, IEEE, and Pierre Pinson, Senior Member, IEEE, “Very-Short-Term Probabilistic Wind Power Forecasts by Sparse Vector Autoregression”, IEEE TRANSACTIONS ON SMART GRID, VOL. 7, NO. 2, March 2016, pp. 763-770.
[NPL 2] Shyh-Jier Huang, Senior Member, IEEE, and Kuang-Rong Shih, “Short-Term Load Forecasting Via ARMA Model Identification Including Non-Gaussian Process Considerations”, IEEE TRANSACTIONS ON POWER SYSTEMS, VOL. 18, NO. 2, May 2003, pp. 673-679.

### SUMMARY OF INVENTION

### Technical Problem

A conventional time-series prediction model cannot predict an event whose time is determined by utilizing future event information.

The present invention has been made in light of the above circumstances, and has an object to provide a prediction device, a prediction method, and a prediction program that utilize information on future events to make predictions.

### Solution to Problem

An aspect of the present invention is a prediction device. A prediction device includes a model generation unit, a prediction value error calculation unit, a difference error calculation unit, an update weight learning unit, and a model update unit. The model generation unit generates a base model of a prediction model configured to predict a future value using information on a future event. The prediction value error calculation unit acquires a real-time observation value, and calculates a prediction error between the real-time observation value and a prediction value by a prediction model. The difference error calculation unit acquires a real-time observation value and calculates a difference error between the real-time observation value and a prediction value by the prediction model. The update weight learning unit acquires a prediction error and a difference error, and updates the update weight to minimize a total error between the prediction value and the real-time observation value at a plurality of past times. The model update unit reads out the latest update weight from the update weight learning unit, and updates a model parameter of the prediction model using the latest update weight and at least one of a prediction error and a difference error at a plurality of past times.

An aspect of the present invention is a prediction method. The prediction method includes a step of generating a base model of a prediction model configured to predict a future value using information on a future event, a step of acquiring a real-time observation value and calculating a prediction error between the real-time observation value and a prediction value by the prediction model, a step of acquiring the real-time observation value and calculating a difference error between the real-time observation value and a prediction value by the prediction model, a step of acquiring the prediction error and the difference error and updating an update weight to minimize a total error between the prediction value and the real-time observation value at a plurality of past times, and a step of reading out the latest update weight and updating a model parameter of the prediction model using the latest update weight and at least one of the prediction error and the difference error at a plurality of past times.

An aspect of the present invention is a prediction program. The prediction program causes a computer having a processor and a storage device to execute at least some of the functions of the components of the prediction device described above.

### Advantageous Effects of Invention

According to the present invention, there are provided a prediction device, a prediction method, and a prediction program that perform prediction using information on future events.

### BRIEF DESCRIPTION OF DRAWINGS

FIG. 1 is a block diagram illustrating a software configuration of a prediction device according to the embodiment.

FIG. 2 is a block diagram illustrating a hardware configuration of the prediction device according to the embodiment.

FIG. 3 is a flowchart illustrating a flow of processing executed by the prediction device according to the embodiment.

FIG. 4 is a diagram illustrating an example of a base model of a prediction model.

FIG. 5 is a diagram illustrating a prediction error.

FIG. 6 is a diagram illustrating a difference of a prediction value and a difference of an observation value.

FIG. 7 is a diagram illustrating a difference error.

### DESCRIPTION OF EMBODIMENTS

Hereinafter, embodiments according to the present invention will be described with reference to the drawings.

### (Software Configuration)

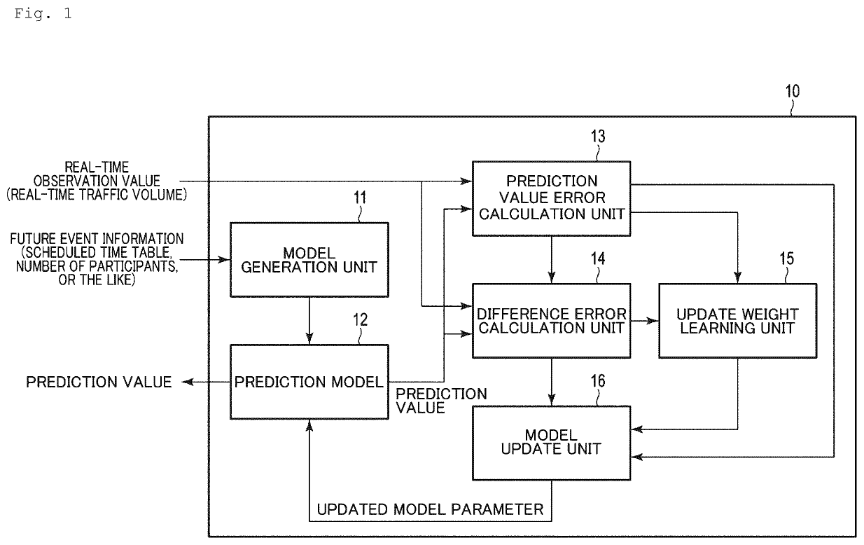

First, a software configuration of a prediction device 10 according to the embodiment will be described with reference to FIG. 1. FIG. 1 is a block diagram illustrating a software configuration of the prediction device according to the embodiment.

The prediction device 10 includes a model generation unit 11, a prediction value error calculation unit 13, a difference error calculation unit 14, an update weight learning unit 15, and a model update unit 16.

The model generation unit 11 generates a base model of a prediction model 12 configured to predict a future value using information on a future event. The base model of the prediction model 12 is a model before the model parameter of the prediction model 12 is updated. The information on the future event includes a scheduled time table, the number of participants, and the like.

A real-time observation value is input to the prediction device 10 at every time. The real-time observation value is, for example, a traffic volume of communication. The real-time observation value is not limited to this, and may be the load of event-related services.

The prediction model 12 predicts a future value and outputs the prediction value to the prediction value error calculation unit 13 and the difference error calculation unit 14. The predicted future value is, for example, a traffic volume.

The prediction value error calculation unit 13 acquires a real-time observation value and calculates a prediction error between the real-time observation value and a prediction value by the prediction model 12. The prediction error at a time t is given by the difference between the prediction value at the time t and the real-time observation value at the time t. A prediction value error calculation unit 13 outputs the calculated prediction error to the difference error calculation unit 14, the update weight learning unit 15, and the model update unit 16.

The difference error calculation unit 14 acquires a real-time observation value and calculates a difference error between the real-time observation value and a prediction value by the prediction model 12. The difference error at the time t is given by the difference between the difference of the prediction value at the time t and the difference of the real-time observation value at the time t. The difference of the prediction value at the time t is given by the difference between the prediction value at the time t and the prediction value at the time (t−1). The difference of the real-time observation value at the time t is given by the difference between the real-time observation value at the time t and the real-time observation value at the time (t−1). The difference error calculation unit 14 outputs the calculated difference error to the update weight learning unit 15 and the model update unit 16.

The update weight learning unit 15 acquires the prediction error and the difference error, and updates the update weight to minimize the total error of the prediction value and the real-time observation value at a plurality of past times.

The model update unit 16 reads out the latest update weight from the update weight learning unit 15, and updates a model parameter of the prediction model 12 using the latest update weight and at least one of the prediction error and the difference error at a plurality of past times. The model update unit 16 outputs the updated model parameter to the prediction model 12.

The prediction model 12 predicts a future value based on the updated model parameter, and outputs the prediction value to the prediction value error calculation unit 13 and the difference error calculation unit 14.

### Hardware Configuration

Next, the hardware configuration of the prediction device 10 will be described. For example, the prediction device 10 is constituted by a computer in terms of hardware. The computer is, for example, a personal computer or a server computer.

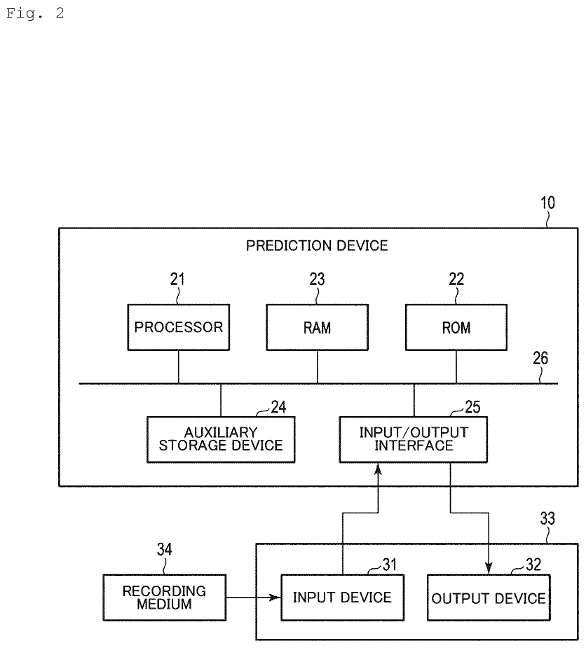

FIG. 2 is a block diagram illustrating a hardware configuration of the prediction device 10 according to the embodiment. As illustrated in FIG. 2, the prediction device 10 includes a processor 21, a read only memory (ROM) 22, a random access memory (RAM) 23, an auxiliary storage device 24, and an input/output interface 25.

The processor 21, the ROM 22, the RAM 23, the auxiliary storage device 24, and the input/output interface 25 are electrically connected to each other via a bus 26, and perform exchange of data via the bus 26.

The processor 21 is configured of a general-purpose hardware processor including, for example, a central processing unit (CPU) and a graphical processing unit (GPU). The processor 21 controls the whole of the ROM 22, the RAM 23, the auxiliary storage device 24, and the input/output interface 25.

The ROM 22 is a nonvolatile memory constituting a part of the main storage device. The ROM 22 stores a startup program required at the start of the processor 21 non-temporarily. The processor 21 is started by executing a program in the ROM 22. The ROM 22 is configured of, for example, an erasable programmable read only memory (EPROM), and stores settings at the time of starting in addition to a startup program.

The RAM 23 is a volatile memory constituting a part of the main storage device. The RAM 23 temporarily stores a program necessary for processing of the processor 21 and data necessary for executing the program. The RAM 23 calculates data in the RAM 23 by executing a program in the RAM 23 by the processor 21, and stores the calculation result in the RAM 23.

The auxiliary storage device 24 is constituted of a nonvolatile memory such as a hard disk drive (HDD), a solid state drive (SSD), or the like. The auxiliary storage device 24 stores a program executed by the processor 21 and data necessary for executing the program non-temporarily. The processor 21 reads out the program and data in the auxiliary storage device 24 into the RAM 23, and executes the program to execute various functions.

The input/output interface 25 is connected to an external input device 31, an output device 32, and the like, and enables input of the information from the input device 31 and output of the information to the output device 32. For example, the input/output interface 25 may be a wired interface or a wireless interface. The wired interface includes a port or the like to which the device is connected. The wireless interface includes Bluetooth (Registered Trademark), WiFi (Registered Trademark), and the like.

The input device 31 may include a keyboard, a mouse, a touch panel, a receiving device, a disk drive, and the like. The input device 31 is not limited thereto, and may include any other input equipment. The output device 32 may include a display, a transmission device, a disk drive, or the like. The output device 32 is not limited thereto and may be configured of any other output equipment. The input device 31 and the output device 32 may be constituted by an input/output device 33 having both functions.

The input device 31 has a function of inputting information on a future event and real-time observation data to the prediction device 10. The output device 32 has a function of outputting a prediction value by the prediction model 12 from the prediction device 10 to the outside.

The program non-temporarily stored in the auxiliary storage device 24 is provided to the prediction device 10, for example, via a recording medium 34 on which the program is non-temporarily recorded and which can be read by the prediction device 10. Such a recording medium 34 is called a non-transitory computer readable recording medium. Examples of non-transitory computer-readable recording media include disks such as flexible disks, optical disks (CD-ROM, CD-R, DVD-ROM, DVD-R, or the like), magneto-optical disks (MO, or the like), semiconductor memory, or the like.

The programs non-temporarily stored in the auxiliary storage device 24 include a prediction program. The prediction program causes a computer constituting the prediction device 10 to execute at least some of functions of the model generation unit 11, the prediction value error calculation unit 13, the difference error calculation unit 14, the update weight learning unit 15, and the model update unit 16.

In a case where the recording medium 34 is a disk, the program stored non-temporarily in the auxiliary storage device 24 is stored via the disk drive which is the input device 31 and the input/output interface 25, or in a case where the recording medium 34 is a semiconductor memory, the program is read into the auxiliary storage device 24 via the port that is the input/output interface 25 and stored non-temporarily. In addition, the program may be stored in a server on the network, downloaded from the server, and non-temporarily stored in the auxiliary storage device 24.

The processor 21 executes a program in the ROM 22 at the time of starting of the prediction device 10, reads out an OS in the RAM 23 and starts it. The processor 21 monitors instruction input, connection of external equipment, and the like under the control of the OS. In addition, the processor 21 sets a program area and a data area in the RAM 23 under control by the OS. In response to an instruction input to start the prediction device 10, the processor 21 loads the prediction program from the auxiliary storage device 24 into the program area of the RAM 23, and also loads data required for executing the prediction program from the auxiliary storage device 24 into the data area of the RAM 23. The processor 21 calculates data in the data area according to the prediction program, and writes the calculation result in the data area. By such an operation, the processor 21, the RAM 23, the auxiliary storage device 24, the input/output interface 25, and the bus 26 cooperate to execute the functions of at least some of the components of the prediction device 10.

### Operation

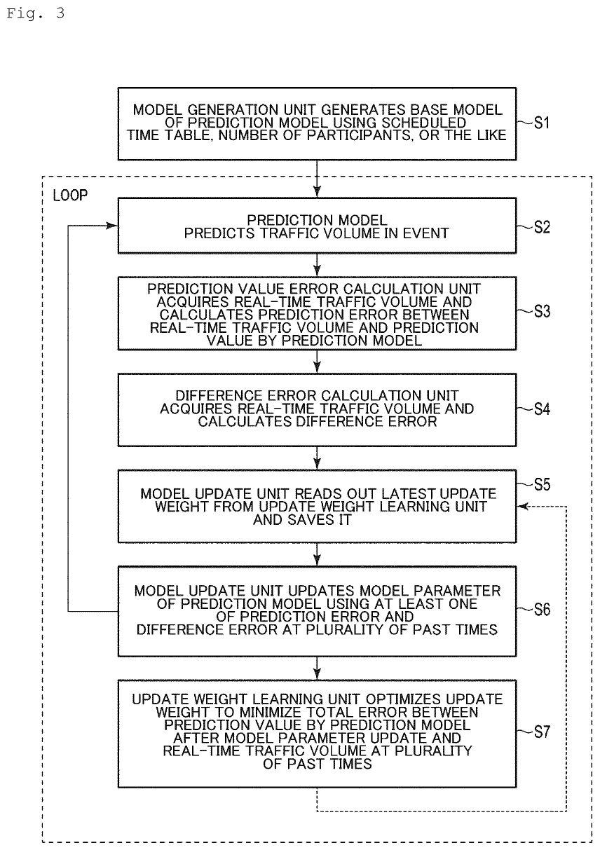

Next, the operation of the prediction device 10 will be described with reference to FIG. 3. FIG. 3 is a flowchart illustrating a flow of processing executed by the prediction device 10. Hereinafter, an example will be described in which an event is a sports game having a single break time and the traffic volume in the live distribution service of the video of each player to the audience in the stadium is predicted.

### Step S1

The model generation unit 11 generates a base model of the prediction model 12 configured to predict the traffic volume using a scheduled time table, the number of participants, and the like. The traffic volume can be expressed by one function having a plurality of variables including time or a combination of a plurality of functions, and can be approximated using past data. The base model of the prediction model 12 is expressed by Equation (1).

$$\begin{matrix}[ Math . 1 ] & \\ {y}_{t}^{base} = F ( t , {T}_{start} , {T}_{Middle - start} , {T}_{Middle - end ,} {T}_{end} , n , loc ) & ( 1 )\end{matrix}$$

Here, F is one function or a combination of a plurality of functions described above, and t is time, Tₛₜₐᵣₜ, T_{middle-start}, T_{middle-end}, and T_{end} are time points, n is the number of participants, and loc is positional information. Tₛₜₐᵣₜ is an event start time, T_{middle-start} is a break start time, T_{middle-end} is a break end time, and T_{end} is an event end time.

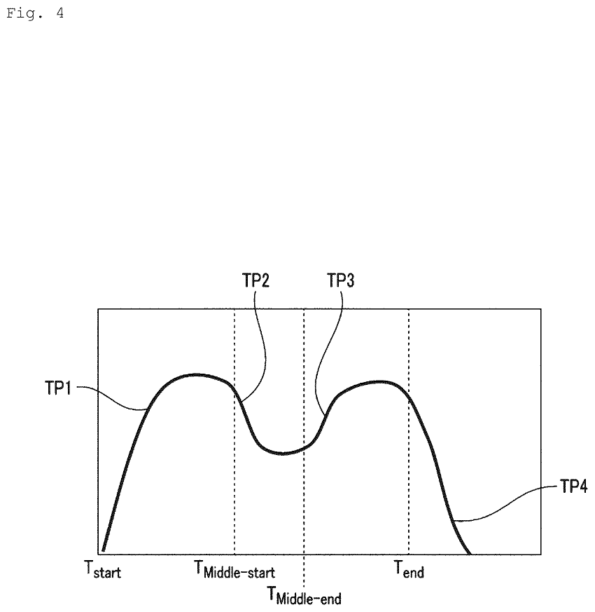

FIG. 4 illustrates an example of a base model of the prediction model 12. In this example, this model is a model in which since many persons view video images for each player in a stadium after the start of a game in a period TP1, the traffic volume increases to an upper limit, after that, it remained near the upper limit, in a period TP2, the number of people who are watching a video for each player at an intermediate break sharply decreases to reduce a traffic volume, and in a period TP3, after the start of the latter half game, people who watch the video of each player gradually increase and traffic volume gradually increases, and in a period TP4, after the end of the game, the traffic volume is reduced.

### Step S2

The prediction model 12 predicts a traffic volume in the event. The prediction model 12 outputs a prediction value of the predicted traffic volume to the prediction value error calculation unit 13 and the difference error calculation unit 14.

### Step S3

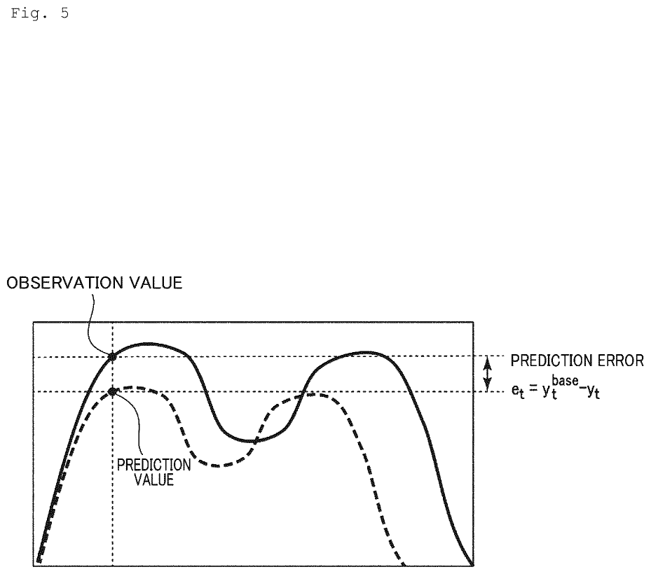

The prediction value error calculation unit 13 acquires a real-time traffic volume and calculates a prediction error between the real-time traffic volume and a prediction value by the prediction model 12. The prediction errors are illustrated in FIG. 5. The prediction error at the time t is given by the difference between the prediction value at the time t and the real-time observation value at the time t. That is, the prediction error at the time t is given by Equation (2).

$$\begin{matrix}[ Math . 2 ] & \\ {e}_{t} = {y}_{t}^{base} - {y}_{t} & ( 2 )\end{matrix}$$

The prediction value error calculation unit 13 outputs the calculated prediction error to the difference error calculation unit 14, the update weight learning unit 15, and the model update unit 16.

### Step S4

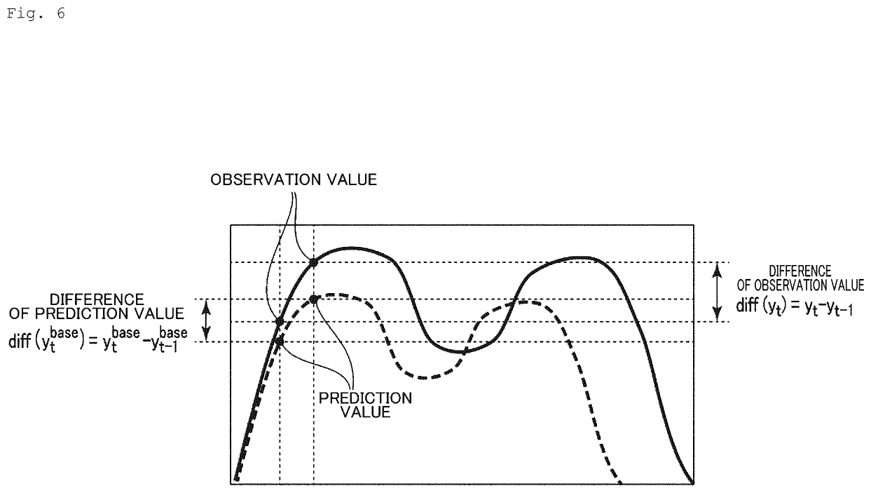

The difference error calculation unit 14 acquires a real-time traffic volume and calculates a difference error between the real-time traffic volume and a prediction value by the prediction model 12. When calculating the difference error, at first, the difference error calculation unit 14 calculates the difference of the prediction value at the time t and the difference of the real-time traffic volume. FIG. 6 illustrates the difference between the prediction values and the difference between the real-time traffic volumes. The difference tends to increase if it is equal to or greater than 0, is maintained at present if it is 0, and tends to decrease if it is equal to or less than 0. In the example illustrated in FIG. 6, it is assumed that more people than expected will participate and the match will be extended.

The difference of the prediction value at the time t is given by the difference between the prediction value at the time t and the prediction value at the time (t−1). That is, the difference between the prediction values at the time t is given by Equation (3).

$$\begin{matrix}[ Math . 3 ] & \\ diff ( {y}_{t}^{base} ) = {y}_{t}^{base} - {y}_{t - 1}^{base} & ( 3 )\end{matrix}$$

The difference of the real-time traffic volume at the time t is given by the difference between the real-time traffic volume at the time t and the real-time traffic volume at the time (t−1). That is, the difference of the real-time traffic volume at the time t is given by Equation (4).

$$\begin{matrix}[ Math . 4 ] & \\ diff ( {y}_{t} ) = {y}_{t} - {y}_{t - 1} & ( 4 )\end{matrix}$$

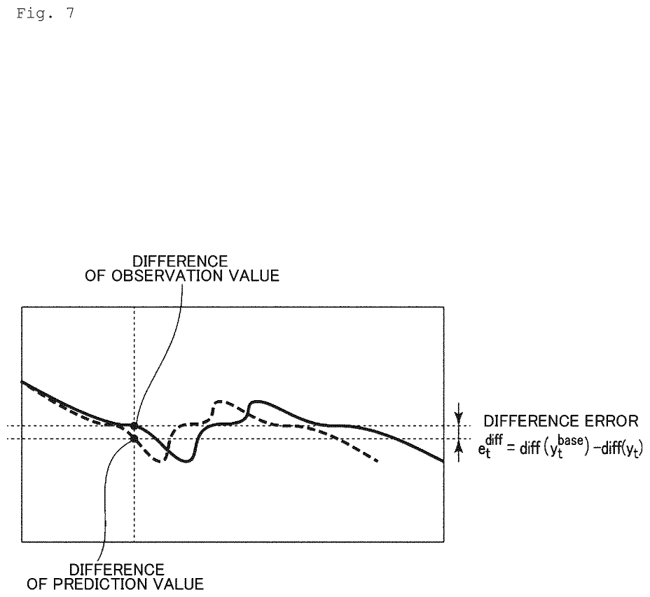

Next, the difference error calculation unit 14 calculates a difference error from the difference of the prediction value and the difference of the real-time traffic volume. The difference errors are illustrated in FIG. 7. The difference error is useful for detecting the difference between the model assumed change tendency and the actual change tendency. The difference error at the time t is given by the difference between the difference of the prediction value at the time t and the difference of the real-time observation value at the time t. That is, the difference error at time t is given by Equation (5).

$$\begin{matrix}[ Math . 5 ] & \\ {e}_{t}^{diff} = diff ( {y}_{t}^{base} ) - diff ( {y}_{t} ) & ( 5 )\end{matrix}$$

The difference error calculation unit 14 outputs the calculated difference error to the update weight learning unit 15 and the model update unit 16.

### Step S5

The model update unit 16 reads out the latest update weight from the update weight learning unit 15 and stores it.

### Step S6

The model update unit 16 uses the update weights (θ, α, β, γ) saved by the model update unit 16 to update the model parameter using at least one of the prediction error and the difference error at the past k-time points. The model parameter is, for example, the number of participants and the time point.

The model update unit 16 updates the number of participants according to Equation (6).

$$\begin{matrix}[ Math . 6 ] & \\ {n}_{t} ← {n}_{t - 1} + {θ}_{1} {e}_{t - 1} + {θ}_{2} {e}_{t - 2} + … + {θ}_{k} {e}_{t - k} & ( 6 )\end{matrix}$$

The model update unit 16 updates the time points according to Equations (7), (8), and (9).

$$\begin{matrix}[ Math . 7 ] & \\ {T}_{Middle - start}^{t} ← {T}_{Middle - start}^{t - 1} + {α}_{1} {e}_{t - 1}^{diff} + {α}_{2} {e}_{t - 2}^{diff} + … + {α}_{k} {e}_{t - k}^{diff} & ( 7 )\end{matrix}$$

$$\begin{matrix}[ Math . 8 ] & \\ {T}_{Middle - end}^{t} ← {T}_{Middle - end}^{t - 1} + {β}_{1} {e}_{t - 1}^{diff} + {β}_{2} {e}_{t - 2}^{diff} + … + {β}_{k} {e}_{t - k}^{diff} & ( 8 )\end{matrix}$$

$$\begin{matrix}[ Math . 9 ] & \\ {T}_{end}^{t} ← {T}_{end}^{t - 1} + {γ}_{1} {e}_{t - 1}^{diff} + {γ}_{2} {e}_{t - 2}^{diff} + … + {γ}_{k} {e}_{t - k}^{diff} & ( 9 )\end{matrix}$$

### Step S7

The update weight learning unit 15 learns update weights (θ, α, β, γ) to minimize the total error for the past k time points. Equation (10) is an equation for updating θ. Also, the updating of α, β, and γ can be performed in the same manner. An existing optimizer can be used for updating. The model update unit 16 outputs the updated model parameter to the prediction model 12.

$$\begin{matrix}[ Math . 10 ] & \\ {θ}_{1} ∼ {θ}_{k} ← arg min {\sum }_{i = t - k}^{i = t - 1} \vert {y}_{i}^{base} - {y}_{i} \vert = arg min {\sum }_{i = t - k}^{i = t - 1} \vert F ( i , {T}_{start} , {T}_{Middle - start}^{i - 1} + {α}_{1} {e}_{i - 1}^{diff} + {α}_{2} {e}_{i - 2}^{diff} + … + {α}_{k} {e}_{i - k}^{diff} , {T}_{Middle - end}^{i - 1} + {β}_{1} {e}_{i - 1}^{diff} + {β}_{2} {e}_{i - 2}^{diff} + … + {β}_{k} {e}_{i - k}^{diff} , {T}_{end}^{i - 1} + {γ}_{1} {e}_{i - 1}^{diff} + {γ}_{2} {e}_{i - 2}^{diff} + … + {γ}_{k} {e}_{i - k}^{diff} , {n}_{i - 1} + {θ}_{1} {e}_{i - 1} + {θ}_{2} {e}_{i - 2} + … + {θ}_{k} {e}_{i - k} , loc ) - {y}_{i} \vert & ( 10 )\end{matrix}$$

The above equation means that for each θ (argument) from θ₁ to θₖ, the optimal value of each θ (argument) is taken so as to give the minimum value of

$${\sum }_{i = t - k}^{i - t - 1} \vert {y}_{i}^{base} - {y}_{i} \vert .$$

### (LOOP)

Steps S2 to S7 surrounded by the broken lines are repeatedly executed. Steps S2 to S6 are always executed every time, but Step S7 is not required to be executed every time. Step S7 may be executed at intervals. In some cases, the execution of Step S7 may be omitted.

### Effects

As described above, the prediction device 10 according to the embodiment predicts the real-time traffic volume using future event information (scheduled time table, the number of participants and the like). In a case where a deviation occurs from the schedule, the prediction model 12 is corrected in real-time and is adapted to the progress of an actual event, so that the accuracy of prediction is improved. In the event scene, by predicting the future traffic volume with high accuracy, necessary radio networks, server resources, and the like are proactively prepared according to the communication performance requirements (Intents) of the application, thereby maintaining the user satisfaction of the event application (for example, live distribution of the event) and improving the resource efficiency.

In the embodiment, an example has been described in which the prediction device 10 is constituted by a computer having a processor and a storage device, the storage device stores a prediction program, and the processor executes the prediction program to predict traffic volume. However, the prediction program may cause the processor to execute some of the functions of the prediction device 10, that is, by a combination with a program already recorded in a computer, the prediction program may be configured to cause the processor to execute the function of the prediction device 10. The prediction program may also cause a processor to execute the functions of the prediction device 10 in combination with hardware such as a programmable logic device (PLD), a field programmable gate array (FPGA), or a graphic processing unit (GPU).

Hereinabove, embodiments of the present invention have been described above with reference to the drawings. However, the above-mentioned embodiment is merely an example of a configuration for embodying the present invention. That is, it is clear that the present invention is not limited to the above-described embodiment. Accordingly, additions, omissions, substitutions, and other modifications of the components may be made within a scope that does not depart from the technical spirit and scope of the present invention.

In short, the present invention is not limited to the foregoing embodiments and can be modified in various forms within the range of the present invention without departing from the gist of the present invention in an execution stage. The embodiments may be combined as appropriate. In this case, combined effects can be achieved. Further, the foregoing embodiments include various aspects of the invention, and the various aspects of the invention can be extracted by combinations selected from a plurality of disclosed constituent elements. For example, even when some of all the constituent elements described in the embodiments are deleted, a configuration from which the constituent elements are deleted can be extracted as an aspect of the invention as long as the problems can be solved and the effects can be obtained.

### REFERENCE SIGNS LIST

10 Prediction device
11 Model generation unit
12 Prediction model
13 Prediction value error calculation unit
14 Difference error calculation unit
15 Update weight learning unit
16 Model update unit
21 Processor
22 ROM
23 RAM
24 Auxiliary storage device
25 Input and output interface
26 Bus
31 Input device
32 Output device
33 Input and output device
34 Recording medium
TP1 Period
TP2 Period
TP3 Period
TP4 Period

1. A prediction device comprising:
model generation circuitry that generates a base model of a prediction model configured to predict a future value using information on a future event;
prediction error calculation circuitry that acquires a real-time observation value and calculates a prediction error between the real-time observation value and a prediction value by the prediction model;
difference error calculation circuitry that acquires the real-time observation value and calculates a difference error between the real-time observation value and a prediction value by the prediction model;
update weight learning circuitry that acquires the prediction error and the difference error and updates an update weight to minimize a total error between the prediction value and the real-time observation value at a plurality of past times; and
model update circuitry that reads out the latest update weight from the update weight learning circuitry and updates a model parameter of the prediction model using the latest update weight and at least one of the prediction error and the difference error at a plurality of past times.

2. The prediction device according to claim 1, wherein:
the model update circuitry updates the model parameter of the prediction model using the latest update weight and both the prediction error and the difference error at a plurality of past times.

3. The prediction device according to claim 2, wherein;
the prediction error at a time t is given by the difference between the prediction value at the time t and the real-time observation value at the time t.

4. The prediction device according to claim 3, wherein;
when the prediction value at the time t is defined as
$${y}_{t}^{base} ,$$
and the real-time observation value at the time t is defined as yₜ, the prediction error et is given by the following equation (1):
$${e}_{t} = {y}_{t}^{base} - {y}_{t} . \qquad [ [ … ( 1 ) ] ]$$

5. The prediction device according to claim 3, wherein:
the difference error at the time t is given by a difference between the difference of the prediction value at the time t and the difference of the real-time observation value at the time t,
the difference of the prediction value at the time t is given by the difference between the prediction value at the time t and the prediction value at a time (t−1), and
the difference of the real-time observation value at the time t is given by the difference between the real-time observation value at the time t and the real-time observation value at the time (t−1).

6. The prediction device according to claim 5, wherein;
when the prediction value at the time t is defined as
$${y}_{t}^{base}$$
and the prediction value at the time (t−1) is defined as
$${y}_{t - 1}^{base} ,$$
the difference
$$diff ( {y}_{t}^{base} )$$
of the prediction value at the time t is given by the equation (2) below,
$$diff ( {y}_{t}^{base} ) = {y}_{t}^{base} - {y}_{t - 1}^{base} \qquad [ [ … ( 2 ) ] ]$$
when the real-time observation value at the time t is defined as yₜ, and the real-time observation value at the time (t−1) is defined as yₜ₋₁, the difference diff (yₜ) of the real-time observation value at the time t is given by the equation (3) below, and
$$diff ( {y}_{t} ) = {y}_{t} - {y}_{t - 1} \qquad [ [ … ( 3 ) ] ]$$
the difference error
$${e}_{t}^{diff}$$
at the time t is given by the equation (4) below,
$${e}_{t}^{diff} = diff ( {y}_{t}^{base} ) - diff ( {y}_{t} ) . \qquad [ [ … ( 4 ) ] ]$$

7. A prediction method comprising:
generating a base model of a prediction model configured to predict a future value using information on a future event;
acquiring a real-time observation value and calculating a prediction error between the real-time observation value and a prediction value by the prediction model;
acquiring the real-time observation value and calculating a difference error between the real-time observation value and a prediction value by the prediction model;
acquiring the prediction error and the difference error and updating an update weight to minimize a total error between the prediction value and the real-time observation value at a plurality of past times; and
updating a model parameter of the prediction model using the latest update weight and at least one of the prediction error and the difference error at a plurality of past times.

8. A non-transitory computer readable recording medium storing a prediction program that causes a computer having a processor and a storage device to execute: at least some of the functions of the components of the prediction device according to claim 1.

9. A non-transitory computer readable recording medium storing a prediction program that causes a computer to perform the method of claim 7.
